(19) United States
(12) Patent Application Publication
(10) Pub. No.: US 2026/0180577 A1
(43) Pub. Date: Jun. 25, 2026

(54) SIGNAL ISOLATION CIRCUIT WITH IMPROVED COMMON MODE TRANSIENT IMMUNITY

(71) Applicant: KOREA ELECTROTECHNOLOGY RESEARCH INSTITUTE, Changwon-si (KR)

(72) Inventors: Ki Nam Song, Changwon-Si (KR); Ki Hyun Kim, Changwon-si (KR); Min Yong Jung, Changwon-si (KR)

(73) Assignee: KOREA ELECTROTECHNOLOGY RESEARCH INSTITUTE, Changwon-si (KR)

(21) Appl. No.: 19/538,123

(22) Filed: Feb. 12, 2026

Related U.S. Application Data
(63) Continuation of application No. PCT/KR2025/006401, filed on May 12, 2025.

(30) Foreign Application Priority Data
Jun. 4, 2024 (KR) 10-2024-0073080
Jul. 15, 2024 (KR) 10-2024-0093076

(51) Int. Cl. H03K 19/003; H03K 19/0175; H04L 25/02

(52) U.S. Cl. CPC H03K 19/003; H03K 19/0175; H04L 25/0266

(57) ABSTRACT

A signal isolation circuit with enhanced common mode transient immunity is disclosed. The signal isolation circuit for transferring signals between electrically isolated domains, the signal isolation circuit includes a transmitter configured to generate a second signal by modulating a first signal on a first domain; an isolation core configured to transfer the second signal from the first domain to a second domain; a receiver configured to generate a third signal by demodulating the second signal on the second domain; a pseudo-receiver provided between the transmitter and the isolation core and configured to demodulate the second signal into a fourth signal on the first domain; and a current boost circuit configured to selectively increase an input current supplied to the transmitter or an output current output by the transmitter based on the first signal and the fourth signal.

### CROSS-REFERENCE TO RELATED APPLICATION

The present application is a continuation of International Application No. PCT/KR2025/006401, filed May 12, 2025, which is based upon and claims priority to Korean Patent Application No. 10-2024-0073080, filed on Jun. 4, 2024 in Korea, and Korean Patent Application No. 10-2024-0093076, filed on Jul. 15, 2024 in Korea. The entire disclosures of the above applications are incorporated herein by reference.

### TECHNICAL FIELD

The present disclosure relates to a signal isolation circuit with enhanced common mode transient immunity.

### BACKGROUND ART

The content described below simply provides background information related to the present embodiment and does not constitute the prior art.

A galvanically isolated drive circuit for driving a wide bandgap switching device (e.g., a SiC MOSFET or a GaN FET) usually transfers signals between input and output using magnetic coupling or capacitive coupling methods. To prevent malfunction of the isolated drive circuit, a circuit with strong noise immunity against common-mode transient intervals occurring during signal transfer is required. Such common-mode transient immunity (CMTI) is one of the important characteristics required for a drive circuit. CMTI refers to the ability of an isolated drive circuit to maintain the state of the output signal (high or low) during a transient voltage interval that occurs between different ground potentials of the isolated drive circuit. In the operating process of the isolated drive circuit, the common-mode transient voltage may reach up to 1.5 kV, and CMTI may be expressed in units of V/ns (or kV/μs).

### SUMMARY

At least one aspect of the present disclosure provides a signal isolation circuit for transferring signals between electrically isolated domains. The signal isolation circuit includes a transmitter configured to generate a second signal by modulating a first signal on a first domain; an isolation core configured to transfer the second signal from the first domain to a second domain; a receiver configured to generate a third signal by demodulating the second signal on the second domain; a pseudo-receiver provided between the transmitter and the isolation core and configured to demodulate the second signal into a fourth signal on the first domain; and a current boost circuit configured to selectively increase an input current supplied to the transmitter or an output current output by the transmitter based on the first signal and the fourth signal.

At least another aspect of the present disclosure provides a transmitter circuit for signal transfer to a different domain. The transmitter circuit includes a transmitter configured to generate a second signal by modulating a first signal on a first domain; a pseudo-receiver configured to demodulate the second signal into a fourth signal on the first domain; and a current boost circuit configured to selectively increase an input current supplied to the transmitter or an output current output by the transmitter based on the first signal and the fourth signal.

At least yet another aspect of the present disclosure provides a circuit provided on a transmitter side to prevent malfunction of a signal isolation circuit. The circuit includes a pseudo-receiver configured to demodulate a second signal output from the transmitter into a fourth signal; and a current boost circuit configured to selectively increase an input current supplied to the transmitter or an output current output by the transmitter based on a first signal, which is a modulated into the second signal, and the fourth signal.

In some embodiments, the transmitter may be configured to output the second signal that selectively oscillates based on a level of the first signal. The transmitter outputs the second signal that oscillates based on the first signal having a first logic level, and the pseudo-receiver may be configured to output the fourth signal having different levels according to whether the second signal is oscillating.

In some embodiments, the current boost circuit may be configured to output a fifth signal that triggers an increase of the input current or the output current based on levels of the first signal and the fourth signal

In some embodiments, the current boost circuit may include a comparison circuit configured to compare the level of the first signal with the level of the fourth signal. A level of an output signal of the comparison circuit transitions in response to the fourth signal transitions to a level different from that of the first signal. The comparison circuit may be activated based on the first signal having the first logic level. The level of the output signal transitions from a second logic level to the first logic level in response to the level of the fourth signal transitions from the first logic level to the second logic level.

In some embodiments, the current boost circuit may further include a one-shot trigger circuit configured to generate a sixth signal having a predetermined pulse width in response to a level of an output signal of the comparison circuit transitioning.

In some embodiments, the receiver and the pseudo-receiver may have identical circuit configurations. The receiver and the pseudo-receiver each may include a first circuit configuration for demodulating the second signal. The receiver may further include a second circuit configuration for preventing a glitch in the third signal. The first circuit configuration may include a low-noise amplifier and an envelope detector, and the second circuit configuration may include a low-pass filter.

In some embodiments, the transmitter may include: a cross-coupled LC oscillator configured to generate a signal oscillating at a predetermined frequency; a first switching element configured to selectively enable or disable a path of a first tail current of the cross-coupled LC oscillator based on a level of the first signal; and a second switching element configured to selectively enable or disable a path of a second tail current of the cross-coupled LC oscillator based on an output of the current boost circuit.

In some embodiments, the transmitter may include: a modulation circuit configured to alternatively output one of the first signal and an output signal of an oscillator circuit based on a level of the first signal; and a buffer circuit configured to output the second signal based on an output of the modulation circuit. The buffer circuit may include a plurality of inverters, and a switching element configured to selectively connect some of the plurality of inverters to remaining inverters based on an output of the current boost circuit.

### BRIEF DESCRIPTION OF DRAWINGS

FIG. 1 illustrates a configuration of a signal isolation circuit according to an embodiment of the present disclosure.

FIG. 2 is an exemplary waveform diagram referenced for describing an on-off keying signaling protocol.

FIG. 3 is an exemplary waveform diagram referenced for describing a malfunction caused by a common-mode transient.

FIG. 4 is a waveform diagram referenced for describing an operation of a malfunction-prevention circuit according to an embodiment of the present disclosure.

FIG. 5 illustrates a configuration of a receiver according to an embodiment of the present disclosure.

FIG. 6 illustrates a configuration of a pseudo-receiver according to an embodiment of the present disclosure.

FIGS. 7 and 8 are circuit diagrams illustrating current boost circuits according to various embodiments of the present disclosure.

FIGS. 9 and 10 are exemplary circuit diagrams referenced for describing an example in which a malfunction-prevention circuit according to an embodiment of the present disclosure is applied to a magnetically coupled galvanically isolated signal isolation circuit.

FIGS. 11 and 12 are exemplary circuit diagrams referenced for describing an example in which a malfunction-prevention circuit according to an embodiment of the present disclosure is applied to a capacitively coupled galvanically isolated signal isolation circuit.

FIG. 13 is an exemplary circuit diagram referenced for describing another example in which a malfunction-prevention circuit according to an embodiment of the present disclosure is applied to a magnetically coupled galvanically isolated signal isolation circuit.

FIG. 14 is an exemplary waveform diagram referenced for describing signal transfer malfunction that may occur when signal strength of on-off keying modulation decreases.

FIG. 15 is a waveform diagram referenced for describing an operation of a malfunction-prevention circuit according to an embodiment of the present disclosure.

### DETAILED DESCRIPTION

The present disclosure may provide a circuit capable of preventing a malfunction caused by common-mode transients or by similar malfunctions resulting from various other factors such as temperature, process, and power supply variations; and a signal isolation circuit including the same.

Features of the present disclosure are not limited to the aforementioned features, and other features not described above may be evidently understood by a person having ordinary skill in the art to which the present disclosure pertains from the following description.

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

In describing the components of an embodiment according to the present disclosure terms such as first, second, i), ii), a), b), etc., may be used. Such terms are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary.

The following detailed description, together with the accompanying drawings, is intended to describe example embodiments of the present disclosure, and is not intended to represent the only embodiments in which the present disclosure may be practiced.

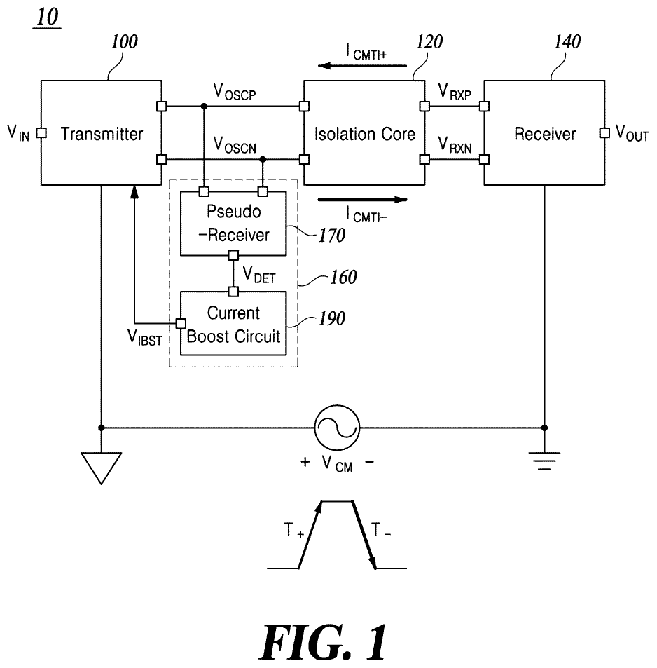

FIG. 1 illustrates a configuration of a signal isolation circuit according to an embodiment of the present disclosure.

A signal isolation circuit 10 is a device that electrically isolates a plurality of domains while enabling transfer of specific digital signals between the domains. The signal isolation circuit 10 may include, for example, a digital isolator. The plurality of domains may have different power supply levels or may have separate power sources for their respective operations.

As illustrated in FIG. 1, the signal isolation circuit 10 according to an embodiment of the present disclosure may include all or part of a transmitter 100, an isolation core 120, a receiver 140, and a malfunction-prevention circuit 160. The components illustrated in FIG. 1 represent functionally distinct elements, and at least one of the components may be implemented in an integrated form in an actual physical environment.

An input signal V_{IN} of the signal isolation circuit 10 is modulated by the transmitter 100 located in a first domain, transferred to a second domain through the isolation core 120, and restored through demodulation by the receiver 140. The transmitter 100 and the receiver 140 may modulate or demodulate signals based on an on-off keying (OOK) topology. The isolation channel (or isolation barrier) applied to the isolation core 120 may employ, but is not limited to, a micro-transformer, capacitors, magneto-resistors/giant magneto-resistors, or opto-electric devices, and the present disclosure does not specify any particular method for implementation thereof.

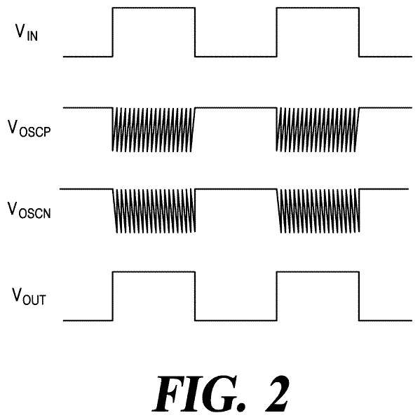

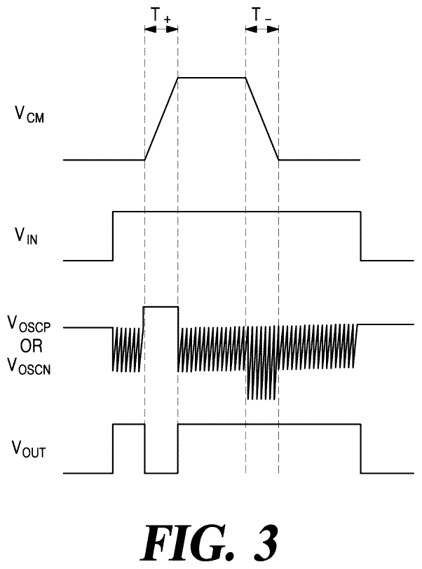

FIG. 2 is an exemplary waveform diagram referenced for describing an on-off keying signaling protocol. FIG. 3 is an exemplary waveform diagram referenced for describing a malfunction caused by a common-mode transient.

As shown in FIG. 2, OOK is a method for representing a digital signal according to the presence or absence of a carrier wave. For example, when the level of the input signal V_{IN} is high, the input signal V_{IN} is modulated into high-frequency signals V_{OSCP} and V_{OSCN}, transferred through an isolation channel, and then restored to an output signal V_{OUT} having a high level through demodulation.

Meanwhile, when a common-mode transient voltage V_{CM} occurs between the ground of the first domain and the ground of the second domain, common-mode transient currents I_{CMTI+} and I_{CMTI-} are induced by the capacitive components of the isolation core 120 (in particular, by parasitic capacitances that inevitably exist due to the isolation structure). When the parasitic capacitance is denoted as Cₚₐᵣ, the magnitudes of the common-mode transient currents I_{CMTI+} and I_{CMTI-} may be expressed as shown in Eq. 1.

$${I}_{CMTI} = {C}_{p a r} \cdot \frac{d {V}_{C M}}{d t} \qquad [ Eq . 1 ]$$

The common-mode transient currents I_{CMTI+} and I_{CMTI-} may flow in opposite directions during rising and falling intervals of the common-mode transient voltage V_{CM}. For example, referring to FIG. 1, during a rising interval T₊ of the common-mode transient voltage V_{CM}, a common-mode transient current I_{CMTI+} flowing from the receiver 140 toward the transmitter 100 may be induced, whereas during a falling interval T₋ of the common-mode transient voltage V_{CM}, a common-mode transient current I_{CMTI-} flowing from the transmitter 100 toward the receiver 140 may be induced.

Such common-mode transient currents I_{CMTI+} and I_{CMTI-} may cause malfunction of the transmitter 100 or the receiver 140 used for on-off keying signal transmission. For example, the transmitter 100 may include an oscillator configured to generate a high-frequency carrier signal, where during the rising interval T₊ of the common-mode transient voltage V_{CM}, oscillation of the oscillator may be stopped due to the common-mode transient current I_{CMTI+}. At this time, as shown in FIG. 3, depending on the circuit structure of the oscillator, modulated signals V_{OSCP} and V_{OSCN} output from the transmitter 100 may be fixed at a voltage higher than the supply voltage V_{CC} and, according to the on-off keying signal transmission protocol, the receiver 140 may demodulate the corresponding signal into an output signal V_{OUT} having a logic low level. In other words, during the rising interval T₊ of the common-mode transient voltage V_{CM}, a malfunction may occur in which the output signal V_{OUT} of the signal isolation circuit 10 becomes different from the input signal V_{IN}.

Referring again to FIG. 1, the malfunction-prevention circuit 160 is introduced to prevent malfunction caused by the common-mode transient described above or similar malfunctions caused by various other factors such as temperature, process, or power-supply variations.

The malfunction-prevention circuit 160 may detect a malfunction condition in which the input signal V_{IN} and the output signal V_{OUT} of the signal isolation circuit 10 become different from each other based on modulated signals V_{OSCP} and V_{OSCN} output from the transmitter 100, and may output a triggering signal V_{IBST}. To this end, the malfunction-prevention circuit 160 may include a pseudo-receiver 170 configured to demodulate the modulated signals V_{OSCP} and V_{OSCN}, and a current boost circuit 190 configured to generate the triggering signal V_{IBST} based on a quasi-demodulated signal V_{DET} demodulated by the pseudo-receiver 170. In the present disclosure, the pseudo-receiver 170 may be referred to as a pseudo-receiver.

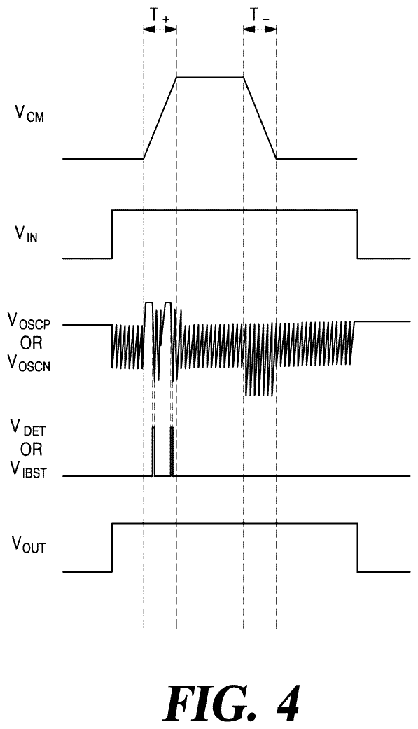

FIG. 4 is a waveform diagram referenced for describing an operation of a malfunction-prevention circuit according to an embodiment of the present disclosure.

Referring to FIG. 4, the malfunction-prevention circuit 160 may detect stoppage of oscillation of modulated signals V_{OSCP} and V_{OSCN} in a time interval during which the transmitter 100 is required to output the oscillating modulated signals (e.g., a time interval in which the input signal V_{IN} has a high level), and may generate a triggering signal V_{IBST}. The triggering signal V_{IBST} may cause an increase in input current supplied to the transmitter 100 or output current generated by the transmitter 100, thereby supporting the modulated signals V_{OSCP} and V_{OSCN} to resume oscillation. The malfunction-prevention circuit 160 may continuously monitor the modulated signals V_{OSCP} and V_{OSCN} and repeatedly generate the triggering signal V_{IBST} each time oscillation of the modulated signals V_{OSCP} and V_{OSCN} stops. In other words, the malfunction-prevention circuit 160 may adaptively respond without additional circuit adjustment even when the length of the rising interval T₊ of the common-mode transient voltage V_{CM} varies. Meanwhile, although the present disclosure mainly describes an example in which malfunction of the transmitter 100 is prevented during the rising interval T₊ of the common-mode transient voltage V_{CM}, the present disclosure is not limited to the specific example. The malfunction-prevention circuit 160 may also be applied, without substantial modification of the technical principles, to a case in which the transmitter 100 malfunctions during the falling interval T₋ of the common-mode transient voltage V_{CM}.

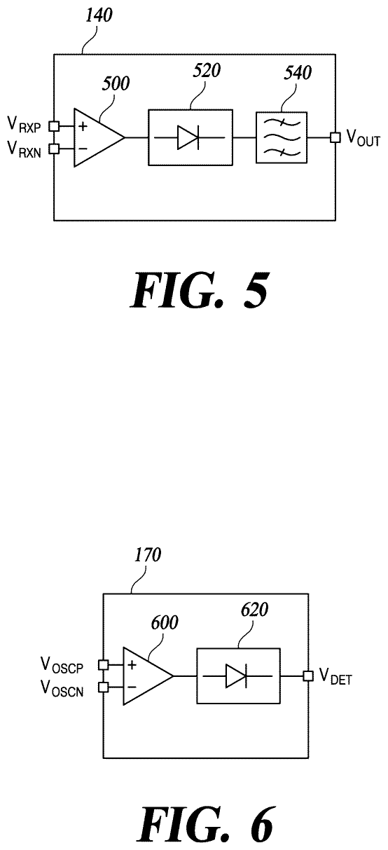

In what follows, various configurations of the pseudo-receiver 170 and the current boost circuit 190 for implementing the operations above will be described with reference to FIGS. 5 to 8.

FIG. 5 illustrates a configuration of a receiver according to an embodiment of the present disclosure. FIG. 6 illustrates a configuration of a pseudo-receiver according to an embodiment of the present disclosure.

Referring to FIGS. 5 and 6, the receiver 140 and the pseudo-receiver 170 may have identical or similar circuit configurations. In other words, in the present disclosure, the pseudo-receiver 170, which has a structure identical or similar to that of the receiver 140, may be arranged on the transmitter 100 side to detect whether the modulated signals V_{OSCP} and V_{OSCN} are oscillating. Having an identical or similar structure between the receiver 140 and the pseudo-receiver 170 may indicate that signals are demodulated based on the same demodulation topology. In some examples, the receiver 140 and the pseudo-receiver 170 may output voltages of different levels according to whether the input signal is oscillating. For example, while the receiver 140 outputs a high-level output signal V_{OUT} when the signals V_{RXP} and V_{RXN} transferred through the isolation core 120 are oscillating, the pseudo-receiver 170 may output a high-level quasi-demodulated signal V_{DET} when the modulated signals V_{OSCP} and V_{OSCN} are not oscillating. In another example, the pseudo-receiver 170 may output a low-level quasi-demodulated signal V_{DET} when the modulated signals V_{OSCP} and V_{OSCN} are not oscillating.

The receiver 140 and the pseudo-receiver 170 may include circuit configurations for demodulating received signals. For example, the receiver 140 may include an envelope detector 520 operating in the second domain, and the pseudo-receiver 170 may include an envelope detector 620 operating in the first domain. In some examples, amplifiers 500 and 600 may be provided at front ends of the envelope detectors 520 and 620, respectively. The amplifier 500 of the receiver 140 may amplify modulated signals V_{RXP} and V_{RXN} transferred through the isolation core 120 and provide the amplified signaled to the envelope detector 520, and the amplifier 600 of the pseudo-receiver 170 may amplify modulated signals V_{OSCP} and V_{OSCN} output from the transmitter 100 and provide the amplified signals to the envelope detector 620. Hear, each amplifier may be a low-noise amplifier (LNA).

The receiver 140 or the pseudo-receiver 170 may further include an additional circuit configuration for a dedicated function. For example, the receiver 140 may further include a low-pass filter 540 to prevent glitches from appearing in the output signal V_{OUT} due to detection delay at the pseudo-receiver 170. Although a filter applied to the receiver 140 increases propagation delay of the signal isolation circuit 10 and thus needs to be minimized to ensure data transfer rate, since the glitch in the output signal V_{OUT} caused by response delay of the pseudo-receiver 170 falls in the range of several nanoseconds or lower, the glitch may be removed using a short filter capable of minimizing reduction in the data transfer rate.

Meanwhile, any type of receiver structure supporting the on-off keying protocol may be employed for the receiver 140 and the pseudo-receiver 170. Since a specific structure may vary depending on the type of isolation channel and the type of transmitter 100, the present disclosure is not limited to a particular structure.

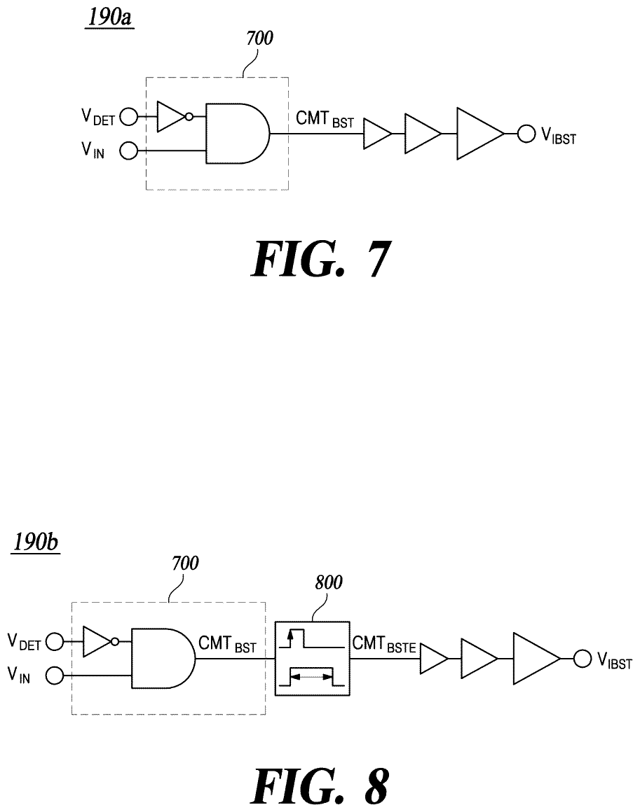

FIGS. 7 and 8 are circuit diagrams illustrating current boost circuits according to various embodiments of the present disclosure.

Referring to FIG. 7, the current boost circuit 190a may include a comparison circuit 700 configured to compare a level of the input signal V_{IN} with a level of a quasi-demodulated signal V_{DET}. The comparison circuit 700 may be implemented as a combinational circuit. Meanwhile, although FIG. 7 illustrates an example in which the comparison circuit 700 includes an inverter and an AND gate, the present disclosure is not limited to the specific example, and various other forms of combinational circuits may also be employed for the comparison circuit.

The comparison circuit 700 may be configured to generate a high-level output CMT_{BST} when the input signal V_{IN} is at a high level and the quasi-demodulated signal V_{DET} is at a low level. For example, during a time interval in which the input signal V_{IN} is at a low level, the comparison circuit 700 may be disabled, and the output CMT_{BST} of the comparison circuit 700 remains at a low level, whereas during a time interval in which the input signal V_{IN} is at a high level, the comparison circuit 700 may be enabled, and the level of the output CMT_{BST} may be determined according to the level of the quasi-demodulated signal V_{DET}. In other words, the quasi-demodulated signal V_{DET}, which represents an interval during which oscillation of the modulated signals V_{OSCP} and V_{OSCN} is stopped, is synchronized with the input signal V_{IN} by the comparison circuit 700; consequently, the malfunction-prevention circuit 160 may be activated when the input signal V_{IN} is at a high level.

When the quasi-demodulated signal V_{DET} transitions from a high level to a low level during a time interval in which the input signal V_{IN} is at a high level, the output CMT_{BST} of the comparison circuit 700 may transition from a low level to a high level. The output CMT_{BST} of the comparison circuit 700 may be converted into a triggering signal V_{IBST} through one or more buffers. Afterward, if oscillation of the modulated signals V_{OSCP} and V_{OSCN} resumes in response to the triggering signal V_{IBST}, the quasi-demodulated signal V_{DET} transitions from a low level to a high level, and the output CMT_{BST} of the comparison circuit 700 and the triggering signal V_{IBST} transition again from a high level to a low level.

Referring to FIG. 8, the current boost circuit 190b may further include a one-shot trigger circuit 800. The one-shot trigger circuit 800 may detect an edge of the output CMT_{BST} of the comparison circuit 700 and output a signal CMT_{BSTE} having a predetermined pulse width. For example, when the quasi-demodulated signal V_{DET} transitions from a high level to a low level during a time interval in which the input signal V_{IN} is at a high level, the output CMT_{BST} of the comparison circuit 700 may transition from a low level to a high level. The one-shot trigger circuit 800 may detect a rising edge of the output CMT_{BST} of the comparison circuit 700 and make the output signal CMT_{BSTE} transition from a low level to a high level. The output signal CMT_{BSTE} may be converted into a triggering signal V_{IBST} through one or more buffers. The output signal CMT_{BSTE} of the one-shot trigger circuit 800 and the triggering signal V_{IBST} may transition again from a high level to a low level after a predetermined time interval has elapsed.

As described above, the current boost circuit 190b may minimize glitches caused by detection delay of the pseudo-receiver 170 by increasing the length of the time interval during which the triggering signal V_{IBST} remains at a high level. Meanwhile, the pulse width extended by the one-shot trigger circuit 800 is extremely short—on the order of several tens of nanoseconds—so that power consumption resulting from the extended pulse width may remain at a low level.

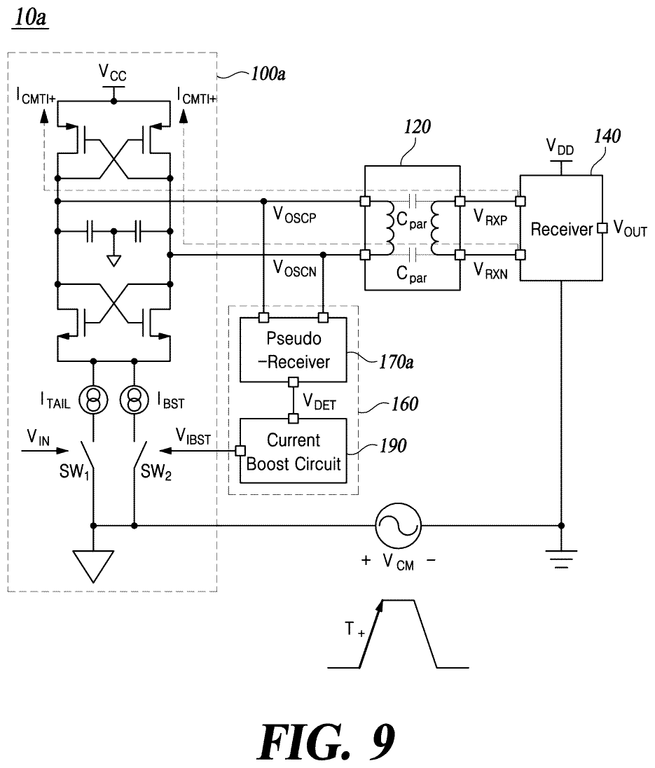

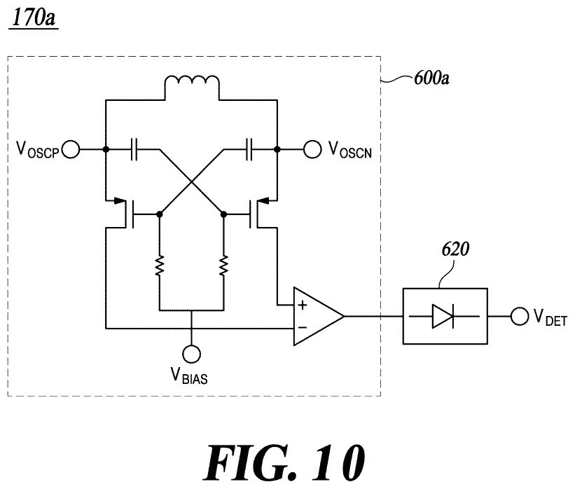

FIGS. 9 and 10 are exemplary circuit diagrams referenced for describing an example in which a malfunction-prevention circuit according to an embodiment of the present disclosure is applied to a magnetically coupled galvanically isolated signal isolation circuit.

FIG. 9 illustrates an example of a magnetically coupled galvanically isolated signal isolation circuit 10a including a malfunction-prevention circuit 160.

As shown in FIG. 9, a transmitter 100a of the magnetically coupled galvanically isolated signal isolation circuit 10a may include a cross-coupled LC oscillator configured to generate a signal oscillating at a predetermined frequency.

In the cross-coupled LC oscillator, a first switching element SW1 may be connected to selectively enable or disable a path of a first tail current I_{TAIL} of the cross-coupled LC oscillator based on a level of an input signal V_{IN}. For example, when the input signal V_{IN} has a high level, the first switching element SW1 is turned on, and the path of the first tail current I_{TAIL} is enabled, thereby starting the operation of the cross-coupled LC oscillator to generate high-frequency modulated signals V_{OSCP} and V_{OSCN}.

When a sufficiently large common-mode transient current I_{CMTI+} is introduced toward the output side of the cross-coupled LC oscillator due to a rise in the common-mode transient voltage V_{CM}, oscillation of the modulated signals V_{OSCP} and V_{OSCN} stops. The modulated signals V_{OSCP} and V_{OSCN} may be fixed at voltages higher than the supply voltage V_{CC} because of the body-diode voltage drop of the transistors (e.g., P-channel Metal-Oxide-Semiconductor Field Effect Transistors (MOSFETs) connected to the supply voltage V_{CC}) included in the cross-coupled LC oscillator.

To increase the tail current of the cross-coupled LC oscillator under the above condition, a second switching element SW2, which selectively enable or disable the path of the second tail current I_{BST} of the cross-coupled LC oscillator based on the level of a boosting signal V_{IBST}, may be additionally connected to the cross-coupled LC oscillator. For example, when the triggering signal V_{IBST} transitions to a high level by the malfunction-prevention circuit 160, the second switching element SW2 is turned on, and the path of the second tail current I_{BST} is enabled; as a result, the total tail current of the cross-coupled LC oscillator may increase, and oscillation of the modulated signals V_{OSCP} and V_{OSCN} may be resumed.

FIG. 10 illustrates an example of a pseudo-receiver 170a configured to detect oscillation (or stoppage of oscillation) of the modulated signals V_{OSCP} and V_{OSCN} output from the cross-coupled LC oscillator.

Referring to FIG. 10, the pseudo-receiver 170a may include a capacitor cross-coupled LNA 600a configured to amplify high-frequency modulated signals V_{OSCP} and V_{OSCN} generated by the cross-coupled LC oscillator. Meanwhile, in the example of FIG. 10, considering that the cross-coupled LC oscillator outputs a high-level signal when the input signal is at a low level, the capacitor cross-coupled LNA 600a is designed using P-channel MOSFETs; however, the present disclosure is not limited to the specific design.

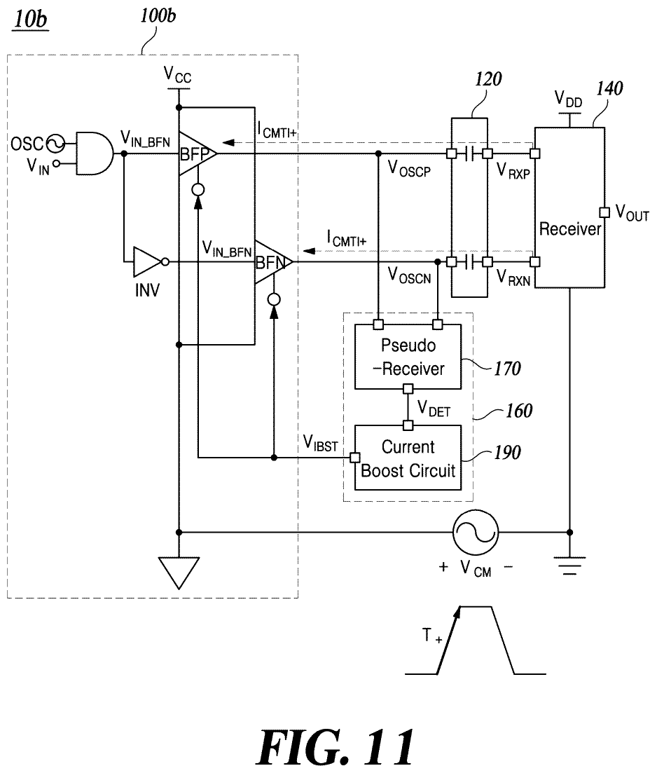

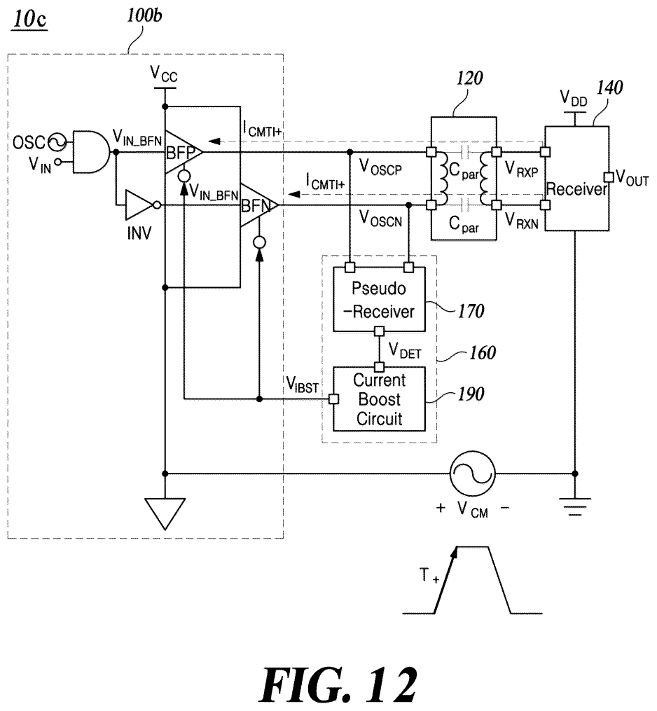

FIGS. 11 and 12 are exemplary circuit diagrams referenced for describing an example in which a malfunction-prevention circuit according to an embodiment of the present disclosure is applied to a capacitively coupled galvanically isolated signal isolation circuit.

FIG. 11 illustrates an example of a capacitively coupled galvanically isolated signal isolation circuit 10b including a malfunction-prevention circuit 160.

As illustrated in FIG. 11, the transmitter 100b of the capacitively coupled galvanically isolated signal isolation circuit 10b may perform on-off keying modulation by AND-gating an output signal of an oscillator OSC with an input signal V_{IN}. The output V_{IN_BFP} of the AND gate may be selected as either the input signal V_{IN} or the output signal of the oscillator, depending on the level of the input signal V_{IN}. The oscillator OSC may be, for example, a ring oscillator or a voltage-controlled oscillator (VCO). In some examples, the oscillator and the AND gate may collectively be referred to as a modulation circuit.

To enable the high-frequency signal V_{IN_BFP} output from the modulation circuit to be transferred across the isolation barrier of the isolation core 120, buffer circuits BFP and BFN may be provided between the modulation circuit and the isolation core 120. A plurality of buffer circuits BFP and BFN and inverters may be used to generate differential-type modulated signals V_{OSCP} and V_{OSCN} from a single-ended signal V_{IN_BFP}.

Meanwhile, when the rate of voltage change dV_{CM}/dt of the common-mode transient voltage V_{CM} is high, a common-mode transient current I_{CMTI+} having magnitude greater than the current capacity of the buffer circuits BFP and BFN may be introduced toward the output side of the buffer circuits BFP and BFN. In this case, the buffer circuits BFP and BFN may fail to properly transfer the high-frequency signal V_{IN_BFP}, and the output voltage of the buffer circuits BFP and BFN may become fixed to the supply voltage V_{CC} or ground.

The malfunction-prevention circuit 160 may detect stoppage of oscillation of the modulated signals (V_{OSCP} and V_{OSCN} caused by the malfunction and may generate a triggering signal V_{IBST} that causes the output current of the buffer circuits (BFP and BFN to increase.

FIG. 12 illustrates an example of buffer circuits BFP and BFN configured to selectively increase output current capacity.

As shown in FIG. 12, the buffer circuits BFP and BFN may include an inverter chain 1200 in which a plurality of inverters are sequentially connected, at least one additional inverter 1220 configured to provide extra current capacity, and a switching element SW configured to selectively connect the inverter chain 1200 and the additional inverter 1220. The switching element SW may be controlled by the triggering signal V_{IBST}. For example, when the triggering signal V_{IBST} has a high level, the switching element SW is turned on, and the last inverter of the inverter chain 1200 and the additional inverter 1220 may be connected in parallel. In other words, the additional inverter 1220 may help resume oscillation of the modulated signals V_{OSCP} and V_{OSCN} by increasing the output current of the buffer circuits BFP and BFN when oscillation of the modulated signals V_{OSCP} and V_{OSCN} is stopped.

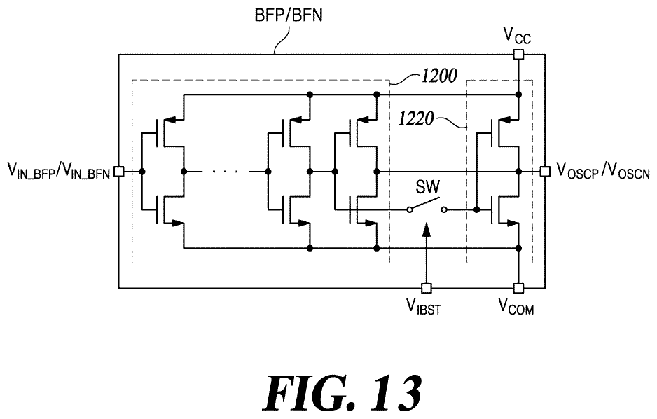

FIG. 13 is an exemplary circuit diagram referenced for describing another example in which a malfunction-prevention circuit according to an embodiment of the present disclosure is applied to a magnetically coupled galvanically isolated signal isolation circuit.

Referring to FIG. 13, the transmitter 100b described above may also be applied to a magnetically coupled galvanically isolated signal isolation circuit 10c. For example, the malfunction-prevention circuit 160 may detect malfunction of the transmitter 100b occurring during a falling interval of a secondary-side potential through the pseudo-receiver 170, thereby preventing output of the receiver 140 from being incorrectly demodulated.

In the description above, it was assumed that common-mode transient is one example of causes of malfunction in the signal isolation circuit; however, the present disclosure may be applied, without substantial modification of its technical principles, to signal transmission malfunctions caused by various other factors.

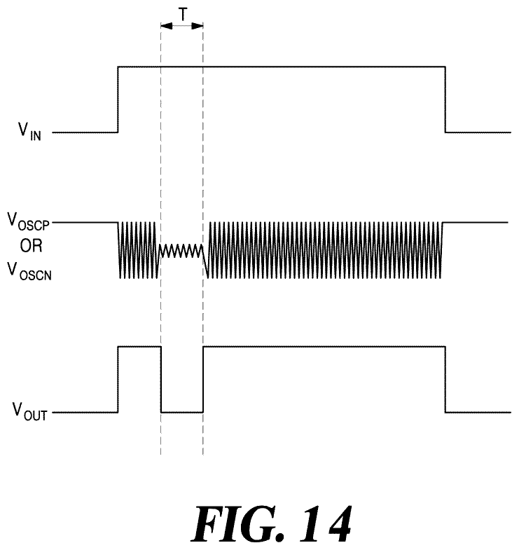

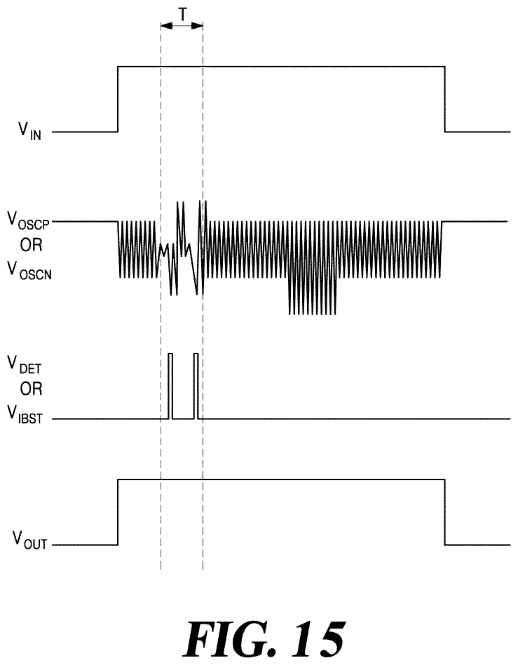

FIG. 14 is an exemplary waveform diagram referenced for describing signal transfer malfunction that may occur when signal strength of on-off keying modulation decreases. FIG. 15 is a waveform diagram referenced for describing an operation of a malfunction-prevention circuit according to an embodiment of the present disclosure.

Referring to FIG. 14, the signal strength of on-off keying modulation may decrease due to various factors such as temperature change, process variation, supply voltage fluctuation, or electromagnetic interference (EMI); as a result, a signal transfer malfunction may occur between the transmitter 100, 100a, or 100b and the receiver 140. For example, during a time interval T shown in FIG. 14, although the input signal V_{IN} of the transmitter is at a high level, an output signal V_{OUT} having a low level due to signal transfer malfunction may be demodulated.

Referring to FIG. 15, the malfunction-prevention circuit 160 according to various embodiments of the present disclosure or the signal isolation circuits 10, 10a, 10b, or 10c including the same may detect stoppage of oscillation of the modulated signals V_{OSCP} and V_{OSCN} during a time interval in which the transmitter 100, 100a, or 100b is required to output the oscillating modulated signals V_{OSCP} and V_{OSCN} (e.g., a time interval in which the input signal V_{IN} is at a high level) and may generate a triggering signal V_{IBST}. The triggering signal V_{IBST} may increase an input current supplied to the transmitter 100, 100a, or 100b or an output current generated by the transmitter 100, 100a, or 100b, thereby helping the modulated signals V_{OSCP} and V_{OSCN} resume oscillation. The malfunction-prevention circuit 160 may continuously monitor the modulated signals V_{OSCP} and V_{OSCN} and repeatedly generate the triggering signal V_{IBST} whenever oscillation of the modulated signals V_{OSCP} and V_{OSCN} are stopped. In other words, the malfunction-prevention circuit 160 may adaptively respond without additional circuit adjustment even when the length of the time interval T in which the signal transmission malfunction occurs varies.

Each element of the device or method in accordance with the present invention may be implemented in hardware or software, or a combination of hardware and software. The functions of the respective elements may be implemented in software, and a microprocessor may be implemented to execute the software functions corresponding to the respective elements.

Various embodiments of systems and techniques described herein can be realized with digital electronic circuits, integrated circuits, field programmable gate arrays (FPGAs), application specific integrated circuits (ASICs), computer hardware, firmware, software, and/or combinations thereof. The various embodiments can include implementation with one or more computer programs that are executable on a programmable system. The programmable system includes at least one programmable processor, which may be a special purpose processor or a general purpose processor, coupled to receive and transmit data and instructions from and to a storage system, at least one input device, and at least one output device. Computer programs (also known as programs, software, software applications, or code) include instructions for a programmable processor and are stored in a “computer-readable recording medium.”

The computer-readable recording medium may include all types of storage devices on which computer-readable data can be stored. The computer-readable recording medium may be a non-volatile or non-transitory medium such as a read-only memory (ROM), a random access memory (RAM), a compact disc ROM (CD-ROM), magnetic tape, a floppy disk, or an optical data storage device, in addition, the computer-readable recording medium may further include a transitory medium. Furthermore, the computer-readable recording medium may be distributed over computer systems connected through a network, and computer-readable program code can be stored and executed in a distributive manner.

Although operations are illustrated in the flowcharts/timing charts in this specification as being sequentially performed, this is merely an exemplary description of the technical idea of one embodiment of the present disclosure. In other words, those skilled in the art to which one embodiment of the present disclosure belongs may appreciate that various modifications and changes can be made without departing from essential features of an embodiment of the present disclosure, that is, the sequence illustrated in the flowcharts/timing charts can be changed and one or more operations of the operations can be performed in parallel. Thus, flowcharts/timing charts are not limited to the temporal order.

According to an embodiment of the present disclosure, malfunction caused by common-mode transients during operation of a signal isolation circuit may be prevented. Accordingly, the common-mode transient immunity (CMTI) of the signal isolation circuit may be improved. In addition, malfunctions similar to those caused by various other factors such as temperature, process, or power-supply variations may also be eliminated.

A malfunction-prevention circuit according to an embodiment of the present disclosure may be applied to transmitters of various types of signal isolation circuits (e.g., magnetically coupled galvanically isolated signal isolation circuits and capacitively coupled galvanically isolated signal isolation circuits) without substantial modification of the underlying technical principles, thereby providing high applicability.

According to an embodiment of the present disclosure, by connecting a pseudo-receiver having a structure similar to that of a receiver to a transmitter side, current flowing to the transmitter may be adaptively increased, and power-consumption efficiency thereof may be improved. For example, buffer current of the transmitter may be adaptively adjusted whenever a malfunction occurs. In another example, tail current of an oscillator may be adaptively adjusted whenever a malfunction occurs. This approach results in lower power consumption compared with a method in which the tail current of the oscillator is increased for a fixed period of time to maintain oscillation. Also, a single malfunction-prevention circuit may cope with a wide range of transient voltage rate (e.g., approximately 300 V/ns), thereby eliminating the need for additional circuit area or power consumption.

The technical effects of the present disclosure are not limited to the technical effects described above, and other technical effects not mentioned herein may be understood to those skilled in the art to which the present disclosure belongs from the description below.

Although exemplary embodiments of the present disclosure have been described for illustrative purposes, those skilled in the art will appreciate that various modifications, additions, and substitutions are possible, without departing from the idea and scope of the claimed invention. Therefore, exemplary embodiments of the present disclosure have been described for the sake of brevity and clarity. The scope of the technical idea of the present embodiments is not limited by the illustrations. Accordingly, one of ordinary skill would understand that the scope of the claimed invention is not to be limited by the above explicitly described embodiments but by the claims and equivalents thereof.

1. A signal isolation circuit for transferring signals between electrically isolated domains, the signal isolation circuit comprising:
a transmitter configured to generate a second signal by modulating a first signal on a first domain;
an isolation core configured to transfer the second signal from the first domain to a second domain;
a receiver configured to generate a third signal by demodulating the second signal on the second domain;
a pseudo-receiver provided between the transmitter and the isolation core and configured to demodulate the second signal into a fourth signal on the first domain; and
a current boost circuit configured to selectively increase an input current supplied to the transmitter or an output current output by the transmitter based on the first signal and the fourth signal, wherein the current boost circuit includes a comparison circuit configured to compare the level of the first signal with the level of the fourth signal, and a level of an output signal of the comparison circuit transitions in response to the fourth signal transitions to a level different from that of the first signal.

2. The signal isolation circuit of claim 1, wherein the transmitter is configured to output the second signal that selectively oscillates based on a level of the first signal, and
the pseudo-receiver is configured to output the fourth signal having different levels according to whether the second signal is oscillating.

3. The signal isolation circuit of claim 1, wherein the current boost circuit is configured to output a fifth signal that triggers an increase of the input current or the output current based on levels of the first signal and the fourth signal.

4. The signal isolation circuit of claim 1, wherein the transmitter outputs the second signal that oscillates based on the first signal having a first logic level, and
the comparison circuit is activated based on the first signal having the first logic level, and
a level of the output signal transitions from a second logic level to the first logic level in response to the level of the fourth signal transitions from the first logic level to the second logic level.

5. The signal isolation circuit of claim 1, wherein the current boost circuit further includes a one-shot trigger circuit configured to generate a sixth signal having a predetermined pulse width based on an edge of the output signal of the comparison circuit.

6. The signal isolation circuit of claim 1, wherein the receiver and the pseudo-receiver have identical circuit configurations.

7. The signal isolation circuit of claim 6, wherein the receiver and the pseudo-receiver each include a first circuit configuration for demodulating the second signal, and
the receiver further includes a second circuit configuration for preventing a glitch in the third signal.

8. The signal isolation circuit of claim 7, wherein the first circuit configuration includes a low-noise amplifier and an envelope detector, and
the second circuit configuration includes a low-pass filter.

9. The signal isolation circuit of claim 1, wherein the transmitter comprises:
a cross-coupled LC oscillator configured to generate a signal oscillating at a predetermined frequency;
a first switching element configured to selectively enable or disable a path of a first tail current of the cross-coupled LC oscillator based on a level of the first signal; and
a second switching element configured to selectively enable or disable a path of a second tail current of the cross-coupled LC oscillator based on an output of the current boost circuit.

10. The signal isolation circuit of claim 1, wherein the transmitter comprises:
a modulation circuit configured to alternatively output one of the first signal and an output signal of an oscillator circuit based on a level of the first signal; and
a buffer circuit configured to output the second signal based on an output of the modulation circuit,
wherein the buffer circuit comprises:
a plurality of inverters; and
a switching element configured to selectively connect some of the plurality of inverters to remaining inverters based on an output of the current boost circuit.

11. A transmitter circuit for signal transfer to a different domain, the transmitter circuit comprising:
a transmitter configured to generate a second signal by modulating a first signal on a first domain;
a pseudo-receiver configured to demodulate the second signal into a fourth signal on the first domain; and
a current boost circuit configured to selectively increase an input current supplied to the transmitter or an output current output by the transmitter based on the first signal and the fourth signal, wherein the current boost circuit includes a comparison circuit configured to compare the level of the first signal with the level of the fourth signal, and a level of an output signal of the comparison circuit transitions in response to the fourth signal transitions to a level different from that of the first signal.

12. The transmitter circuit of claim 11, wherein the transmitter outputs the second signal that oscillates based on the first signal having a first logic level, and
the comparison circuit is activated based on the first signal having the first logic level, and
a level of the output signal transitions from a second logic level to the first logic level in response to the level of the fourth signal transitions from the first logic level to the second logic level.

13. The transmitter circuit of claim 11, wherein the current boost circuit further includes a one-shot trigger circuit configured to generate a sixth signal having a predetermined pulse width based on an edge of the output signal of the comparison circuit.

14. The transmitter circuit of claim 11, wherein the transmitter comprises:
a cross-coupled LC oscillator configured to generate a signal oscillating at a predetermined frequency;
a first switching element configured to selectively enable or disable a path of a first tail current of the cross-coupled LC oscillator based on a level of the first signal; and
a second switching element configured to selectively enable or disable a path of a second tail current of the cross-coupled LC oscillator based on an output of the current boost circuit.

15. The transmitter circuit of claim 11, wherein the transmitter comprises:
a modulation circuit configured to alternatively output one of the first signal and an output signal of an oscillator circuit based on a level of the first signal; and
a buffer circuit configured to output the second signal based on an output of the modulation circuit,
wherein the buffer circuit comprises:
a plurality of inverters; and
a switching element configured to selectively connect some of the plurality of inverters to remaining inverters based on an output of the current boost circuit.

16. A circuit provided on a transmitter side to prevent malfunction of a signal isolation circuit, the circuit comprising:
a pseudo-receiver configured to demodulate a second signal output from the transmitter into a fourth signal; and
a current boost circuit configured to selectively increase an input current supplied to the transmitter or an output current output by the transmitter based on a first signal, which is a modulated into the second signal, and the fourth signal, wherein the current boost circuit includes a comparison circuit configured to compare the level of the first signal with the level of the fourth signal, and a level of an output signal of the comparison circuit transitions in response to the fourth signal transitions to a level different from that of the first signal.

17. The circuit of claim 16, wherein the current boost circuit further includes a one-shot trigger circuit configured to generate a sixth signal having a predetermined pulse width based on an edge of the output signal of the comparison circuit.
